(19) United States
(12) Patent Application Publication
(10) Pub. No.: US 2008/0137319 A1
(43) Pub. Date: Jun. 12, 2008

(54) Arrangement for Shielding Motherboards with a Shielding Metal Plate

(75) Inventors: Werner Bobrowski, Regenstauf (DE); Claus Peter, Regensburg (DE); Dietmar Schlegel, Regensburg (DE); Johann Schneeberger, Neunburg v. W. (DE)

Correspondence Address: LERNER GREENBERG STEMER LLP, P O BOX 2480, HOLLYWOOD, FL, 33022-2480, US

(73) Assignee: SIEMENS VDO AUTOMOTIVE AG, Munchen (DE)

(21) Appl. No.: 11/815,024

(22) PCT Filed: Nov. 22, 2005
(86) PCT No.: PCT/EP05/56128

§ 371 Date: Jul. 30, 2007

(30) Foreign Application Priority Data
Jan. 28, 2005 (DE) 10 2005 004 158.2

(51) Int. Cl. H05K 9/00

(52) U.S. Cl. 361/816

(57) ABSTRACT

A motherboard is shielded by way of a shielding metal sheet. A shielding metal sheet according to the invention is embodied such that the dimensions thereof in the longitudinal and transverse direction do not exceed the dimensions of the motherboard, thus advantageously allowing the shielding metal plate to be mounted directly on the motherboard. By directly mounting the shielding metal plate on the motherboard, the motherboard can also be transported or mounted on a main board as a unit along with the protecting shielding metal plate. The novel device is particularly suitable for decentralized parts production processes and finishing processes of entire shielded electronic systems requiring a lot of components, especially for applications in motor vehicles.

The invention relates to an arrangement for shielding a motherboard by means of a shielding metal plate.

In the prior art, motherboards populated with components are mounted onto a mainboard at the terminal equipment manufacturer's facility. In the process, in a first assembly step, the motherboard is soldered by way of backside contact pads to the contact pads of the mainboard in accordance with the circuits contained on said motherboard. In a second assembly step, a shielding metal plate is soldered to the corresponding contact pads of the mainboard, with the shielding metal plate overlapping the entire motherboard.

It is disadvantageous with this approach that mainboards are shipped for final assembly without a prior assembly of a shielding metal plate which would constitute a protection against electrical and mechanical damage. A further disadvantage is the soldering of contacts on the backside of a motherboard to a mainboard and the direct soldering of the shielding metal plate to the mainboard. Furthermore, a subsequent disassembly of these connections requires the entire mainboard to be heated, as a result of which components of the motherboard can suffer damage. Finally, separate transportation operations of shielding metal plate and motherboard necessitate additional production and assembly steps.

The object underlying the present invention is therefore to provide an improved arrangement for direct shielding of a motherboard by means of a shielding metal plate. A further object of the present invention is to ensure that the quality of the connections can be monitored and said connections can be separated again at a later time without major effort.

This object is achieved according to the invention by means of an arrangement for shielding a motherboard having the features recited in claim 1. Advantageous embodiments and developments which can be used individually or in combination with one another are the subject matter of the dependent claims.

According to the invention a shielding metal plate is implemented in such a way that in terms of its length and width the shielding metal plate's dimensions do not exceed the dimensions of the motherboard. In this way it is advantageously achieved that the shielding metal plate can be mounted directly onto the motherboard. A further advantage achieved by directly mounting the shielding metal plate on the motherboard is that the motherboard can also be transported or, as the case may be, mounted on a mainboard as a unit together with the protecting shielding metal plate.

The invention also comprises connecting legs which are oriented inwards or outwards or in sections alternately inwards and outwards. This advantageously minimizes a tilting of the shielding metal plate.

In an embodiment of the invention the shielding metal plate is preferably secured on the motherboard by means of plug-and-socket connections.

Alternatively or in addition hereto, connecting legs preferably are embodied at least in sections on the shielding metal plate for the purpose of securing the shielding metal plate on the motherboard.

In a further preferred embodiment of the invention, the shielding metal plate has at least connecting legs which project in height beyond the side wall of the shielding metal plate. By this means it is advantageously achieved that the shielding metal plate stands on the connecting legs and the edges of the shielding metal plate are slightly raised in height. Electric leads of the motherboard as well as the solder joints provided at the edge of the motherboard and its connecting points for embodying contact pads to the mainboard are therefore not subject to the risk of being short-circuited.

In a further preferred embodiment of the invention the connecting legs are arranged opposite one another. This achieves a simplification of the manufacturing process and consequently a cost saving.

In particular it has proven worthwhile in order to ensure a secure support of the shielding metal plate to provide at least three connecting legs on the motherboard.

The connecting legs can advantageously be secured to the motherboard by means of an adhesive bond.

Alternatively or in addition hereto, the connecting legs are secured to the motherboard by means of a soldered connection. A resilient and subsequently detachable connection is achieved by means of the soldered connections with which ground and the signal leads are connected.

In a further preferred embodiment of the invention, support surfaces are embodied at least in sections, for example at the four corners on the side walls of the shielding metal plate. The support surfaces are implemented slightly shorter in height relative to the connecting legs, with the result that the support surfaces have no direct contact with the motherboard when the connecting legs stand on the motherboard. Advantageously, a reliable soldering of the connecting legs is ensured by this means. Furthermore, additional mechanical stability of the shielding metal plate against potential external mechanical influences is achieved. If the motherboard is subsequently subjected to a great force from above (e.g. in the course of a test or during installation of modules) which results in a deformation of the connecting legs, the support surfaces serve as an additional mechanical prop which prevents a short-circuit with electric leads or solder joints and their connecting points to the edges of the shielding metal plate.

Finally it is proposed to embody notches at the edge of the motherboard. The notches are used for edge contacting of the motherboard to the mainboard. Said edge contacts are controlled on the motherboard side directly via leads which then establish the electrical contact with the mainboard. The geometry of the shielding metal plate advantageously enables the connection of leads on the mainboard side to the edge contacts of the motherboard even after the shielding metal plate has been mounted onto the motherboard.

The present invention is suitable in particular for decentralized parts production processes and finishing processes of entire shielded electronic systems involving a multiplicity of components, especially for applications in motor vehicles.

Further details and advantages of the invention are explained with the aid of an exemplary embodiment and with reference to the accompanying figures, in which:

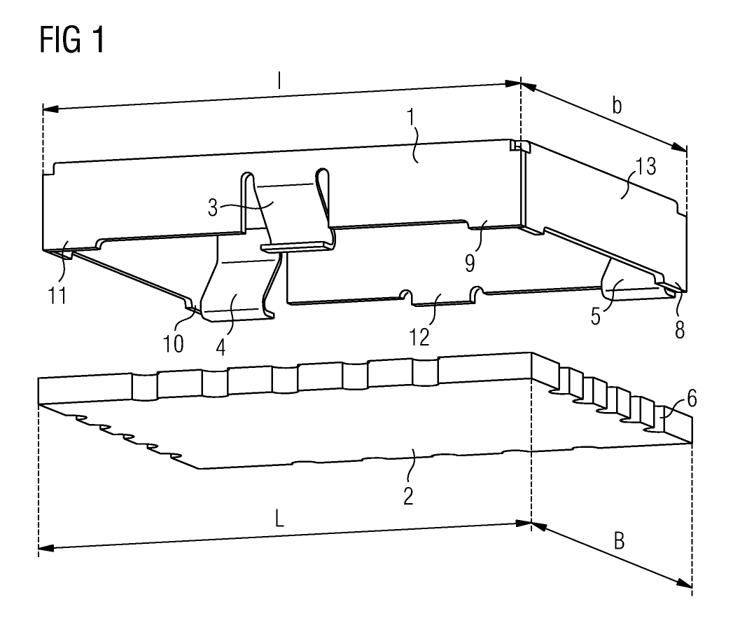

FIG. 1 is a schematic side view of a shielding metal plate which is mounted onto a motherboard; and

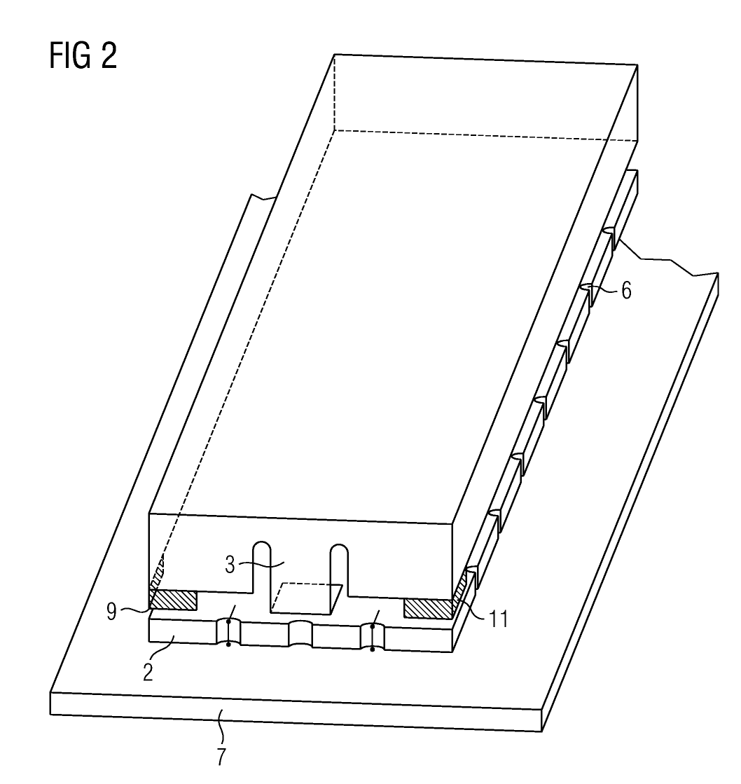

FIG. 2 is a schematic side view of a motherboard which is soldered onto a mainboard and a shielding metal plate which is mounted onto the motherboard.

In the following description of a preferred embodiment of the present invention the same reference characters are used to designate identical or similar components.

FIG. 1 shows a side view of a shielding metal plate 1 which is mounted onto a motherboard 2. The shielding metal plate 1 comprises three connecting legs 3, 4 and 5 which project in height beyond the side wall 13 of the shielding metal plate 1 in a range of tenths of millimeters to a few millimeters. This ensures that when the shielding metal plate 1 is mounted on a motherboard 2 situated immediately beneath it, the support legs 3, 4 and 5 of the shielding metal plate 1 lie on the surface of the motherboard 2 in such a way that the side wall 13 of the shielding metal plate 1 is arranged in a freestanding manner over the motherboard 2. The support surfaces 8, 9, 10, 11 and 12 are raised slightly above the motherboard relative to the connecting legs. The notches 6 at the side edge of the motherboard 2 enable edge contacting to a mainboard 7. The length and width of the shielding metal plate 1 and the motherboard 2 are labeled 1 and b and correspondingly L and B, respectively.

FIG. 2 shows a side view of the motherboard 2 from FIG. 1 which is now soldered on a mainboard 7. The shielding metal plate 1 is mounted onto the motherboard 2 as described with reference to FIG. 1, a connecting leg 3 and two support surfaces 9 and 11 being depicted in each case by way of example. The motherboard 2 is electronically connected to the mainboard 7 via the notches 6 for edge contacting.

Because the notches 6 for the edge contacts are visible externally it is possible to disconnect these at a later time without difficulty. Also shown is the configuration of shielding metal plate 1 and motherboard 2 with the possible securing via connecting legs 3, 4 and 5 as well as with the support surfaces 8, 9, 10, 11 and 12 for stabilizing the shielding metal plate 1. In this arrangement the support surfaces 8, 9, 10, 11 and 12 are implemented slightly shorter in height than the connecting legs 3, 4 and 5 so that in the mounted state of the shielding metal plate 1 on the motherboard 2 the support surfaces 8, 9, 10, 11 and 12 have no direct contact with the motherboard 2. This arrangement can not only be disassembled without major effort; because of its improved accessibility it also permits direct quality tests both on preassembled arrangements and on arrangements mounted on mainboards 7 at the final assembly stage.

According to the invention, the shielding metal plate 1 is preferably embodied with three connecting legs 3, 4 and 5 and five support surfaces 8, 9, 10, 11 and 12, with the connecting legs being soldered accordingly onto the motherboard 2.

In addition, the contact lead which is routed under the connecting leg 3 for the purpose of edge contacting the notch 6 can be routed in a lead plane (not shown) lying spatially thereunder in relation to the motherboard 2. In this way it is ensured that there is no crossing over between the connecting leg 3 and a lead of the motherboard which could lead to a short-circuit.

The present invention is suitable in particular for decentralized parts production processes and finishing processes of entire shielded electronic systems involving a multiplicity of components, especially for applications in motor vehicles.

1-10. (canceled)

11. A shielding configuration for shielding a motherboard, the motherboard having given dimensions, the shielding configuration comprising:
a shielding metal plate having dimensions including a length and a width not exceeding the given dimensions of the motherboard; and
connecting legs for connecting said shielding metal plate to the motherboard, said connecting legs being oriented inwardly or outwardly or in sections alternately inwardly and outwardly.

12. The shielding configuration according to claim 11, wherein said shielding metal plate is retained on the motherboard by plug-and-socket connections formed on the motherboard.

13. The shielding configuration according to claim 11, wherein said connecting legs are embodied at least in sections on said shielding metal plate.

14. The shielding configuration according to claim 11, wherein said shielding metal plate is formed with a side wall and at least two of said connecting legs project beyond said side wall of said shielding metal plate.

15. The shielding configuration according to claim 14, wherein said connecting legs are disposed opposite one another.

16. The shielding configuration according to claim 11, wherein said connecting legs are at least three connecting legs.

17. The shielding configuration according to claim 11, wherein said connecting legs are connected to the motherboard by way of an adhesive bond.

18. The shielding configuration according to claim 11, wherein said connecting legs are soldered to the motherboard.

19. The shielding configuration according to claim 11, wherein said shielding metal plate is formed with side walls, and said side walls are formed with support surfaces at least in sections thereof.

20. The shielding configuration according to claim 11, wherein the motherboard is formed with notches at an edge thereof.

21. A shielding assembly for shielding a motherboard, comprising:
a shielding metal plate formed with shielding metal plate side walls;
at least two connecting legs disposed opposite one another and projecting beyond said side walls of said shielding metal plate, said connecting legs being oriented inwardly or outwardly or alternately inwardly and outwardly; and
support surfaces formed, at least in sections, on said side walls of said shielding metal plate, said support surfaces being raised slightly relative to said connecting legs for retaining said shielding metal plate on the motherboard.

22. An assembly, comprising:
a motherboard having given dimensions; and
a shielding metal plate disposed for shielding said motherboard;
said shielding metal plate having shielding metal plate side walls, support surfaces, and at least two connecting legs;
said support surfaces being formed at least in sections on said side walls of said shielding metal plate, said support surfaces being raised slightly relative to said connecting legs for retaining said shielding metal plate on said motherboard;
said connecting legs being disposed opposite one another and projecting beyond said side walls of said shielding metal plate, said connecting legs being oriented inwardly or outwardly or in sections alternately inwardly and outwardly;
said shielding metal plate having dimensions, including a length and a width, not exceeding the given dimensions of said motherboard.
